(19) United States
(12) Patent Application Publication
(10) Pub. No.: US 2014/0070891 A1
(43) Pub. Date: Mar. 13, 2014

(54) HIGH FREQUENCY AMPLIFIER

(71) Applicant: TDK Corporation, Tokyo (JP)

(72) Inventors: Tomohiko Shibuya, Tokyo (JP); Atsushi Ajioka, Tokyo (JP); Atsushi Tsumita, Tokyo (JP)

(73) Assignee: TDK CORPORATION, Tokyo (JP)

(21) Appl. No.: 14/008,601

(22) PCT Filed: Sep. 20, 2012
(86) PCT No.: PCT/JP2012/073979

§ 371 Date: Sep. 30, 2013

(30) Foreign Application Priority Data
Oct. 17, 2011 (JP) 2011-227809

(51) Int. Cl. H03F 1/32; H03F 3/195

(52) U.S. Cl. CPC H03F 1/32; H03F 3/195
USPC 330/296

(57) ABSTRACT

To prevent a wrap-around signal from an output detection circuit unit that occurs when commonality is achieved between the power supply of the output detection circuit unit and the bias power supply of a power amplification unit. When commonality is achieved between the power supply of a diode of an output detection circuit unit and the power supply of a bias circuit, a resonance circuit is connected between the bias circuit and the output detection circuit unit, thereby preventing a wrap-around signal from the output side of a power amplification transistor from being input to the input side of the power amplification transistor.

### TECHNICAL FIELD

The present invention relates to an amplifier and relates to especially a high frequency amplifier that is provided with a detector circuit that detects high frequency signals.

### BACKGROUND

Recently, data communication by wireless local area network (LAN) represented by IEEE 802.11 standard is widely generalized. Data communication via wireless LAN has been adopted as a signal transmission means as a substitute for cable transmission in, for example: personal computers (PCs); peripheral equipment for PCs such as printers, hard disks, and broadband routers; electronic equipment such as facsimile machines, refrigerators, televisions, cameras, video cameras, and mobile telephones; cars; and airplanes. Wireless data transmission among various electronic devices is commonly performed.

The high frequency amplifier is used in such wireless LANs, mobile telephones, and the like, and is used in a transmission part in a wireless communication device that amplifies and transmits high frequency signals, and the like. The use of such an amplifier is not limited to such a wireless communication device.

In recent years, there has been a modulation system using a multi-carrier, which is represented by an OFDM system such as WiMAX (for example, IEEE802.16-2004, IEEE802.16e-2005 or the like) as a high speed wireless communication standard that covers communication distances of several kilometers, and long term evolution (LTE) as a standard for next generation mobile telephones. When the modulation system is used, waveforms become like waveforms of signals and noise, and a peak to average ratio (PAR), which is a ratio of peak power and average power, becomes large.

In a modulation system such as a QAM modulation system that changes both amplitudes and phases, the volume of information that can be transferred is increased due to multiple valuzation. However, because a margin with respect to noise is decreased, it needs to set a larger preferred carrier to noise ratio (CNR). From such reasons, in a wireless communication device using the modulation system using the multi-carrier or QAM modulation system, a high frequency amplifier in a transmission part should be designed to have a high linearity and large maximum transmission power.

However, a high frequency amplifier that is designed to have high linearity and large maximum transmission power generally tends to have high power consumption. As a result of this, especially in a case when a wireless communication device is a portable device that uses a battery as a power source, it is a concern that battery operation time should be short. To solve such a problem, a configuration in which a supply power source of a detector circuit and a supply power source of a high frequency amplifier are combined.

As a conventional example, a semiconductor device in which a power amplifier and a detector circuit are combined is proposed in JP Laid-open Patent Publication No. 2005-109644 (Patent Document 1). In a power amplification circuit thereof, a capacitor and a transistor are connected in series between an input terminal and an output terminal. The transistor is a bipolar transistor. An emitter is connected to a ground, a base is connected to a capacitor, and a collector is connected to an output terminal

Also, a connection line of the collector and the output terminal is connected to a detector diode of the detector circuit part by the capacitor, and is connected as well to a power source voltage terminal by a resistor. The power source voltage terminal is connected to a direct current voltage source. A connection line of the base and the capacitor of the transistor is connected to the detector diode of the detector circuit part by the resistor, and is connected as well to a bias voltage terminal. The bias voltage terminal is connected to the direct current voltage source. The detector diode of the detector circuit part is made from a transistor in which a short circuit between the base and the collector occurs. On the anode (input side) of the detector diode, the resistor is connected, and the resistor is connected to the base of the transistor.

On the anode (input side) of the above-described detector diode, the capacitor is connected, and the capacitor is connected to the collector of the transistor. The cathode (output side) of the detector diode is connected to the detector output terminal by a connection line. Between the connection line and ground, the capacitor and the resistor are connected in parallel.

Next, performance of the semiconductor device in which the power amplifier and the detector circuit are combined is explained. As well as input signals input from the input terminal to the power amplification circuit and output signals amplified in the transistor are output from the output terminal, detection voltage corresponding to an output level of output signals of the transistor is received from a detector output terminal of the detector circuit part. Because the anode of the diode and the base of the transistor are connected via the resistor, when direct current voltage is applied to a bias voltage terminal, voltage that is almost the same as the base-emitter voltage of the transistor is applied to the diode.

Even when the high frequency signals are not input to the detector circuit part, the detector diode is biased to an almost on-state. Even when signals having a lower power level are input from the capacitor of the power amplification circuit to the detector diode of the power detector circuit, the detector diode operates so that detection voltage can be received from the detector output terminal of the detector circuit part.

Also, as a conventional example, a high frequency power amplifier is proposed in JP Laid-open Patent Publication No. 2007-300262 (Patent Document 2). The power amplifier is provided with a power amplification part including a transistor (power amplification transistor) of which a base terminal is connected to an input terminal via an input matching circuit and of which a collector terminal is connected to an output terminal via an output matching circuit, a bias current supply part that supplies bias current from a direct current power source to a base terminal of a transistor via the transistor (direct current amplification transistor), and an output detector circuit including a diode (detector diode) and connected to an output matching circuit. The power amplifier is configured to supply a current from the direct current power source to an anode terminal of the diode of the output detector circuit via the transistor.

Also, in the bias current supply part, the base terminal of the transistor is connected to the direct current power source via a resistor, a collector terminal is connected to the direct current power source via a resistor, and an emitter terminal is connected to the base terminal of the transistor via a resistor. To the direct current power source, a capacitor is connected.

Furthermore, the emitter terminal of the transistor of the bias current supply part and the anode terminal of the diode of the output detector circuit are connected via a resistor, and a bias current is supplied from the direct current power source to the output detector circuit. In the output detector circuit, the anode terminal of the diode is connected to the output matching circuit via a capacitor. Between ground and a wiring route that connects a cathode terminal of the diode and the detector output terminal, a capacitor and a resistor are connected in parallel.

Next, performance of the high frequency power amplifier in Patent Document 2 is explained. A bias current is supplied from the emitter terminal of the transistor to the diode via the resistor. Therefore, even when there are wrap-around signals (envelope component) that wrap around from the output matching circuit to the base terminal of the transistor via the output detector circuit, amplification of the wrap-around signals by the transistor can be prevented, and the effect of the wrap-around signals on the input signals can be decreased, as the wrap-around signals do not transmit via the transistor.

### PRIOR ART DOCUMENTS

### Patent Documents

Patent document 1: JP Laid-open Patent Publication No. 2005-109644

Patent document 2: JP Laid-open Patent Publication No. 2007-300262

### SUMMARY OF THE INVENTION

### Subjects to be Solved by the Invention

However, in the semiconductor device in Patent Document 1, a bias current is supplied from the direct current power source to the anode terminal of the diode via the diode, and output signals are partially input to an input side of the transistor via the capacitor by wrapping-around. Because wrap-around signals transmit through components such as a capacitor, a resistor, and the like, a phase thereof shifts as compared to input signals. When the wrap-around signals having the shifted phase are input to the transistor, the signals become complex input signals, so that the distortion of output signals becomes large.

Also, when the phase shifts of the input signals and the wrap-around signals become in-phase, abnormal oscillation may occur in the transistor.

Also in the high frequency amplifier of Patent Document 2, a bias current is supplied from the direct current power source to the anode terminal of the diode via a direct current amplification transistor and a resistor. Therefore, a problem similar to the problem of Patent Document 1 may occur.

The present invention has been invented to solve the above-described problems. The objective of the present invention is to provide a high frequency power amplifier that is able to decrease distortion of output signals caused by a high frequency component of the wrap-around signals from the output detector circuit and to suppress the possibility of the occurrence of the abnormal oscillation.

### Means to Solve the Subjects

One example of a high frequency amplifier related to the present invention that achieves the above-described purposes has a first feature that a power amplification part that is connected to an input matching circuit and an output matching circuit, amplifies signals input via the input matching circuit, and outputs the signals to the output matching circuit, an output detector circuit part that is connected to the output matching circuit, a bias circuit that supplies a bias current to an input of the power amplification part and the output detector circuit part, and a resonance circuit that is connected between the bias circuit and the output detector circuit part.

According to the present invention having the above-described feature, because a current is supplied from a direct current power source of the bias circuit to the output detector circuit part via the resonance circuit, wrap-around signals that are partial signals of signals output from the output matching circuit to the output detector circuit part reflect by the resonance circuit, and are not input to the bias circuit side. Therefore, it is possible to prevent the wrap-around signals from being input to an input side of the power amplification part.

As a result, input signals from the input terminal can be prevented from being overlapped with the wrap-around signals, and distortion of output signals can be reduced. Furthermore, there is no wrap-around signal from the output detector circuit part, so that the possibility of abnormal oscillation can be suppressed. Thereby, stable power supply to the power amplification part and the output detector circuit part can be performed.

The high frequency amplifier according to the present invention having the above-described feature has a second feature that a resistor element connected between the bias circuit and the resonance circuit is provided.

According to the present invention having the above-described feature, when the resistor element is connected between the bias circuit and the resonance circuit, it is possible to adjust a current to be supplied to the output detector circuit part. Also, when wrap-around signals including a high harmonic wave component, which are partial signals of signals output from the output matching circuit to the output detector circuit part, are not reflected by the resonance circuit, it is possible to attenuate the wrap-around signals including the high harmonic wave component with the resistor element and suppress wrap-around signals to be input to the input side of the power amplification part.

As a result, input signals from the input terminal can be prevented from being overlapped with the wrap-around signals including the high harmonic wave component, and distortion of output signals can be reduced. Furthermore, there is no wrap-around signal including the high harmonic wave component from the output detector circuit part, so that the possibility of abnormal oscillation can be suppressed. Thereby, stable power supply to the power amplification part and the output detector circuit part can be performed.

The high frequency amplifier according to the present invention having the above-described feature has a third feature that the input matching circuit, the power amplification part, the output detector circuit part, the bias circuit, the resonance circuit, and the resistor element are configured in a semiconductor integrated circuit, the output detector circuit part is connected to the output of the power amplification part, and the resonance circuit is provided with a circuit of a low pass filter type configured with an inductor and a capacitor.

According to the present invention having the above-described feature, the input matching circuit, the power amplification part, the output detector circuit part, the bias circuit, the resonance circuit, and the resistor element are configured by a semiconductor integrated circuit, and because the output detector circuit part is connected to the output of the power amplification part so that the output matching circuit is not arranged on the semiconductor integrated circuit, a chip inductor having a Q value higher than that of an inductor with which the output matching circuit is formed on the semiconductor integrated circuit substrate can be used. As a result, loss of the amplified output signals can be reduced.

Also, because the power amplification part, the bias circuit, and the output detector circuit part are arranged on the same semiconductor integrated circuit substrate, the reduction in size and cost can be realized. Also, when the resonance circuit is not provided, the output signals include signals having a distorted high harmonic wave component as well. Therefore, the distorted high harmonic wave component affects based on the type of modulation signals and the variation in detector voltage may occur. However, when a circuit of a low pass filter type that has a circuit configuration of a resonance circuit and doesn't allow the high harmonic wave component to transmit through is provided, it is possible to suppress the variation in the detector voltage.

The high frequency amplifier according to the present invention having the above-described feature has a fourth feature that, as well as the resonance circuit and the resistor element are configured with chip components, the input matching circuit, the power amplification part, the output detector circuit part, and the bias circuit are connected in the semiconductor integrated circuit, the semiconductor integrated circuit includes an electrode terminal for mounting the resonance circuit and the resistor element, and the chip components of the resonance circuit and the resistor element are mounted on the electrode terminal

According to the present invention having the above-described feature, as well as the resonance circuit and the resistor element are configured by chip components, the input matching circuit, the power amplification part, the output detector circuit part, and the bias circuit are connected by the semiconductor integrated circuit, the semiconductor integrated circuit is provided with the electrode terminal for mounting the resonance circuit and the resistor element. By mounting the chip components of the resonance circuit and the resistor element on the electrode terminal, when a resonance frequency of the resonance circuit shifts due to the variation or the like, although it is not possible to shift a resonance frequency on the semiconductor integrated circuit, it becomes possible to easily correct the resonance frequency only with the change to the chip components according to the present invention. Also, a current from the bias circuit can be arbitrarily adjusted by the resistor element, and a detector voltage value of the output detector circuit part can be adjusted.

### Advantages of the Invention

A high frequency power amplifier of the present invention is able to decrease distortion of output signals caused by a high frequency component of wrap-around signals from an output detector circuit part and to suppress the possibility of the occurrence of abnormal oscillation.

### BRIEF DESCRIPTION OF THE DRAWINGS

FIG. 1 is a block circuit diagram of a high frequency amplifier according to a first embodiment.

FIG. 2 is a block circuit diagram of a high frequency amplifier according to a second embodiment.

FIG. 3 is a block circuit diagram of a high frequency amplifier according to a third embodiment.

### DETAILED DESCRIPTION OF EMBODIMENTS OF THE INVENTION

Hereinafter, embodiments of the present invention are explained with reference to the drawings.

### First Embodiment

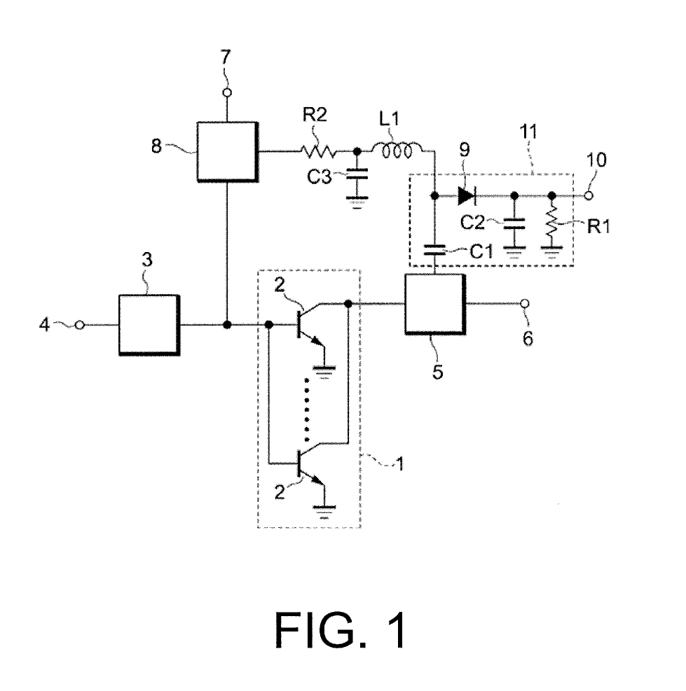

FIG. 1 is a block circuit diagram that shows a configuration of a high frequency amplifier of the present invention according to a first embodiment. FIG. 1 shows a high frequency amplifier having a one stage configuration as an example of high frequency amplifiers. A high frequency amplifier having a multiple stage configuration is also applicable. In FIG. 1, a power amplification part 1 has a plurality of power amplification transistors 2 in parallel. Each of the power amplification transistors 2 in FIG. 1 is a bipolar transistor (HBT), but other transistors that can amplify can be used. For example, a field-effect transistor (FET) can be used. In such a case, a base of the HBT is replaced with a gate of the FET, a collector of the HBT is replaced with a source of the FET, and an emitter of the HBT is replaced with a drain of the FET.

An input terminal 4 is connected to a base terminal of the power amplification transistor 2 via an input matching circuit 3. An output terminal 6 is connected to a collector terminal of the power amplification transistor 2 via an output matching circuit 5. Regarding the input matching circuit 3 and the output matching circuit 5, various circuit configurations may be applicable based on matching conditions, etc. A direct power source (not shown) is connected to a bias supply power source 7. Also, a bias circuit 8 is connected to a bias supply power source terminal, and a bias current is supplied to the base terminal of the power amplification transistor and an output detector circuit part 11, which is described later, from the bias circuit 8.

In the output detector circuit part 11, a capacitor C1 is connected between an anode side of the detector diode 9 and the output matching circuit 5, and a capacitor C2 and a resistor R1 are connected between a ground and a wiring route that connects a cathode side and the detector output terminal 10. Herein, as the detector diode 9, a diode is used. However, a transistor can be used as a substitute for a diode. Also, the output detector circuit part 11 does not necessarily have the circuit configuration of FIG. 1 as long as it is able to output detector voltage.

Also, the anode side of the detector diode 9 is connected to the bias circuit 8 via a resistor element R2, and a capacitor C3 and an inductor L1 for a resonance circuit, and a bias current is supplied. The connection destination of the resistor element R2 via the resonance circuit of the output detector circuit part 11 may be either an output side or an input side of the bias circuit part 8 as long as the connection destination is in a bias supply line. The resonance circuit formed with the capacitor C3 and the inductor L1 resonates at a frequency that reflects input signals. A parallel resonance circuit and the like may be considered for the resonance circuit. However, a circuit of a low pass filter type according to the first embodiment, which can reflect not only a fundamental wave but also a higher harmonic wave, is preferred.

In the present embodiment, because a bias current is supplied to the resistor element R2 and the capacitor C3 and the inductor L1 for the resonance circuit via the diode 9, even when there are wrap-around signals transmitting from the output matching circuit 5 via the output detector circuit part 11, the wrap-around signals are reflected in the resonance circuit formed with the capacitor C3 and the inductor L1. Therefore, it is possible to prevent overlap at the base side of the power amplification transistor 2 via the bias circuit 8, and to eliminate the effect that the wrap-around signals give to the input signals.

Here, because the resistor element R2 is provided, even when there are wrap-around signals having a high frequency component, it is possible to attenuate. However, the resistor element R2 is a resistor element that adjusts voltage to be supplied to the output detector circuit part 11, and it is impossible to attenuate the wrap-around signals completely. Also, when the maximum transmission power is set to be high, it is possible to attenuate the wrap-around signals with the resistor element R2. Therefore, providing the resonance circuit that gives few effects to supply voltage of the output detector circuit part 11 can suppress the distortion of output signals, abnormal oscillation, and the like. Also, a current is supplied from the bias circuit 8 to the output detector circuit part 11 via the resistor element R2 and the resonance circuit. As a result, it is possible to simply adjust the supply current from the bias circuit 8 to the output detector circuit part 11 with the resistor element R2.

### Second Embodiment

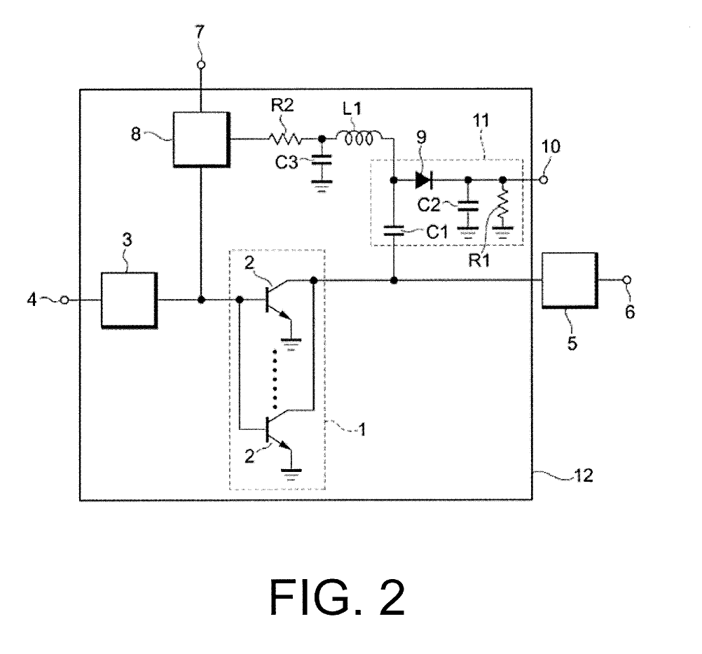

FIG. 2 is a block circuit diagram that shows a configuration of a high frequency amplifier according to a second embodiment of the present invention. In the present embodiment, elements that have different configurations from those of the above-described first embodiment are explained. Specifically, the input matching circuit 3, the power amplification part 1, the output detector circuit part 11, the bias circuit 8, the resonance circuit, and the resistor element R2 are configured by a semiconductor integrated circuit 12, the output detector circuit part 11 is connected to the output of the power amplification part 1, and the resonance circuit is formed by a circuit of a low pass filter type formed with the inductor L1 and the capacitor C3.

In this case, the inductor L1 may be formed by either a spiral inductor or a microstripline. Also, because the output matching circuit 5 is located outside the semiconductor integrated circuit 12, the connection destination of the capacitor C1 of the output detector circuit part 11 is between the collector terminal of the power amplification transistor 2 and the output matching circuit 5. Because the output detector circuit part 11 is connected between the collector terminal of the power amplification transistor 2 and the output matching circuit 5, the output matching circuit 5 is not arranged on the semiconductor integrated circuit. Therefore, when an inductor is used in the output matching circuit 5, a chip inductor having a Q value higher than that of an inductor formed on a semiconductor integrated circuit substrate can be used, and this can reduce loss in the output matching circuit 5.

Also, when the resonance circuit is not provided and when output signals are detected by the output detector circuit part 11 from the connection point, because output signals having a distorted high harmonic wave component are included, there is a fear that the high harmonic wave component affects to cause variation in detector voltage according to the type of modulation signals. However, in the case of the present embodiment, the output signals amplified by the power amplification part 1 include signals having the distorted high harmonic wave component. Therefore, when the resonance circuit is a circuit of a low pass filter type formed with the inductor L1 and the capacitor C3, the high harmonic wave component is not allowed to wrap around to the power supply side, so that it is possible to suppress the variation in the detector voltage. Also, because the input matching circuit 3, the power amplification part 1, the output detector circuit part 11, the bias circuit 8, the resonance circuit, and the resistor element R2 are configured by the semiconductor integrated circuit 12, it is possible to form on the same semiconductor integrated circuit substrate, so that the reduction in size and cost can be realized.

### Third Embodiment

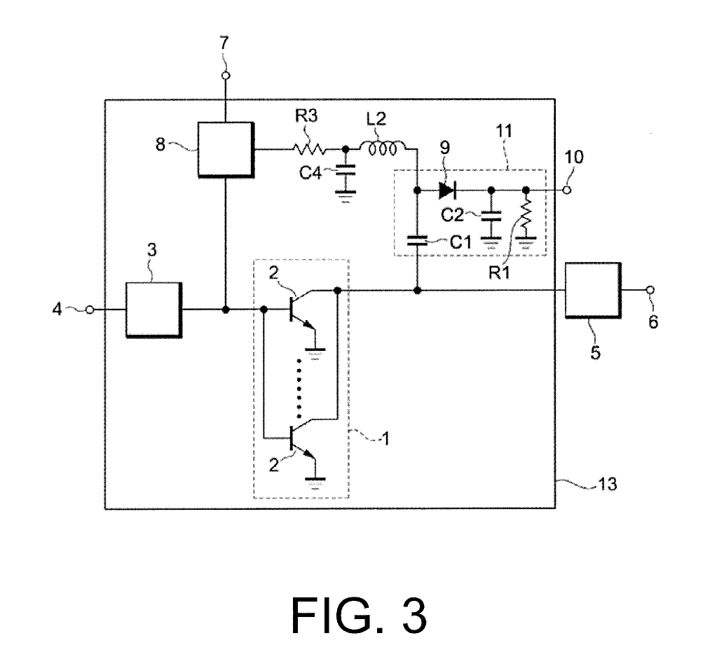

FIG. 3 is a block circuit diagram that shows a configuration of a high frequency amplifier according to a third embodiment of the present invention. In the present embodiment, elements with different configurations from those of the above-described second embodiment are explained. In the present embodiment, the different point is that chip components are used for an inductor L2 and a capacitor C4 that configure a resonance circuit, and a resistor R3. Specifically, the resonance circuit formed with the chip inductor L2 and the chip capacitor C4, and the chip resistor R3 are provided. Furthermore, the resonance circuit formed with the chip inductor L2 and the chip capacitor C4, the resistor element R3, and circuit configurations excluding the output matching circuit part 5 are formed by the semiconductor integrated circuit 13. An electrode terminal on which the resonance circuit formed with the chip inductor L2 and the chip capacitor C4 and the chip component for the resistor element R3 are mounted is provided on the semiconductor integrated circuit substrate. The resonance circuit formed with the chip inductor L2 and the chip capacitor C4 and the chip component for the resistor element R3 are mounted on the electrode terminal

As a result, when a resonance frequency of the resonance circuit shifts due to the variation and the like, although it is not easy to shift the resonance frequency in the semiconductor integrated circuit 13, it is possible to synchronize the resonance frequency easily only with the change to the chip components according to the third embodiment of the present invention. Also, it becomes possible to arbitrarily adjust a current from the bias circuit with the chip resistor R3, so that it becomes possible to adjust a detector voltage value of the output detector circuit part 11.

### INDUSTRIAL UTILITY

As described above, the present invention is related to a high frequency amplifier for, for example, a communication device that transmits and receives high frequency signals, and is suitable to especially a high frequency amplifier having a detector circuit that detects high frequency signals.

### LEGEND

1 Power Amplification Part
2 Power Amplification Transistor
3 Input Matching Circuit
4 Input Terminal
5 Output Matching Circuit
6 Output Terminal
7 Bias Supply Power Terminal
8 Bias Circuit
9 Diode
10 Detector Voltage Output Terminal
11 Output Detector Circuit Part
12, 13 Semiconductor Integrated Circuit
R1, R2, R3 Resistor
L1, L2 Inductor
C1, C2, C3, C4 Capacitor

What is claimed is:

1. A high frequency amplifier, comprising:
a power amplification part that is connected to an input matching circuit and an output matching circuit, that amplifies signals input via the input matching circuit, and that outputs the signals to the output matching circuit;
an output detector circuit part that is connected to the output matching circuit;
a bias circuit that supplies a bias current to the power amplification part and the output detector circuit part; and
a resonance circuit that is located between the bias circuit and the output detector circuit part.

2. The high frequency amplifier according to claim 1, further comprising:
a resistor element that is connected between the bias circuit and the resonance circuit.

3. The high frequency amplifier according to claim 2, wherein
the input matching circuit, the power amplification part, the output detector circuit part, the bias circuit, the resonance circuit, and the resistor element are configured in a semiconductor integrated circuit,
the output detector circuit part is connected to an output of the power amplification part, and
the resonance circuit includes a circuit of a low pass filter type configured with an inductor and a capacitor.

4. The high frequency amplifier according to claim 2, wherein
the resonance circuit and the resistor element are configured with chip components,
the input matching circuit, the power amplification part, the output detector circuit part, and the bias circuit are configured in a semiconductor integrated circuit,
the semiconductor integrated circuit includes an electrode terminal for mounting the resonance circuit and the resistor element,
the chip components of the resonance circuit and the resistor element are mounted on the electrode terminal
